(19) United States
(12) Patent Application Publication
(10) Pub. No.: US 2017/0148966 A1
(43) Pub. Date: May 25, 2017

(54) Surface-Mountable Semiconductor Component and Method for Producing Same

(71) Applicant: OSRAM Opto Semiconductors GmbH, Regensburg (DE)

(72) Inventors: Thomas Schwarz, Regensburg (DE); Frank Singer, Regenstauf (DE)

(21) Appl. No.: 15/318,660

(22) PCT Filed: Jun. 9, 2015
(86) PCT No.: PCT/EP2015/062850

§ 371 Date: Dec. 13, 2016

(30) Foreign Application Priority Data
Jun. 13, 2014 (DE) 10 2014 108 368.7

(51) Int. Cl. H01L 33/62; H01L 33/56; H01L 23/60; H01L 33/50; H01L 31/18; H01L 21/683; H01L 31/02; H01L 31/0203; H01L 31/0232; H01L 33/54; H01L 33/00

(52) U.S. Cl. CPC H01L 33/62; H01L 33/54; H01L 33/56; H01L 23/60; H01L 33/507; H01L 33/505; H01L 33/0095; H01L 21/6835; H01L 31/02002; H01L 31/0203; H01L 31/02327; H01L 31/1876; H01L 31/1892; H01L 2933/0066; H01L 2933/005; H01C 7/12

(57) ABSTRACT

A surface-mountable semiconductor component and a method for producing the same are disclosed. In an embodiment the component includes an optoelectronic semiconductor chip, first and second contact elements and a molded body, wherein the chip includes a semiconductor body having a semiconductor layer sequence with an active region provided for producing and/or receiving electromagnetic radiation and arranged between a first semiconductor layer and a second semiconductor layer, wherein the first contact elements are electrically conductively connected to the first semiconductor layer and the second contact elements are electrically conductively connected to the second semiconductor layer, wherein the molded body at least partially encloses the optoelectronic semiconductor chip, wherein the semiconductor component includes a mounting face formed by a surface of the molded body, and wherein the first and second contact elements protrudes through the molded body in a region of the mounting face.

This patent application is a national phase filing under section 371 of PCT/EP2o15/062850, filed Jun. 9, 2015, which claims the priority of German patent application 10 2014 108 368.7, filed Jun. 13, 2014, each of which is incorporated herein by reference in its entirety.

### TECHNICAL FIELD

The invention provides a surface mountable semiconductor component as well as a method for producing such a semiconductor component.

### BACKGROUND

Surface mountable optoelectronic semiconductor components are known from the prior art, said components comprising a silicone encapsulation which is formed at least on a top side and on side surfaces of the semiconductor component. In said semiconductor components, delamination of the encapsulation may occur due to insufficient adherence between the encapsulation and the semiconductor chip, resulting in air gaps which decrease the efficiency of the semiconductor component. In the worst case, this may even result in a complete detachment of the encapsulation.

Furthermore, semiconductor components are known which have an additional film of silicone formed on the underside of said components, said film acting as a reflector due to the addition of scattering particles of titanium dioxide. Typically, on the one hand, said semiconductor components are produced in that the reflective film of silicone on the underside and on the other hand the encapsulation including conversion elements are formed in succession. Due to the fact that the two elements do not cure at the same time, adhesion problems may occur, posing the risk of a detachment of the semiconductor component at the interface between the two elements.

### SUMMARY OF THE INVENTION

Embodiments provide a surface mountable semiconductor component which has a mechanically stable encapsulation. In particular, embodiments provide a surface mountable semiconductor component which is particularly robust to mechanical stress in the mounted state.

According to at least one embodiment of the surface mountable semiconductor component, said surface mountable semiconductor component comprises an optoelectronic semiconductor chip. The optoelectronic semiconductor chip may be a radiation-receiving or a radiation-emitting semiconductor chip. The semiconductor chip is a luminescence diode chip, such as a light-emitting diode chip or a laser diode chip, for example. Furthermore, it is possible that the optoelectronic semiconductor chip is a photo diode chip. Furthermore, the optoelectronic semiconductor chip may comprise a plurality of such semiconductor chips. The semiconductor component may in particular also comprise a radiation-receiving or a radiation-emitting semiconductor chip.

According to at least one embodiment of the optoelectronic semiconductor component, it is provided that the optoelectronic semiconductor chip comprises a semiconductor body which includes a semiconductor layer sequence comprising an active region for generating and/or receiving electromagnetic radiation, which is arranged between a first semiconductor layer and a second semiconductor layer.

According to at least one embodiment of the optoelectronic semiconductor component, said optoelectronic semiconductor component comprises a molded body which at least partially surrounds the optoelectronic semiconductor chip. Preferably, the molded body is formed to the optoelectronic semiconductor chip at least in places. That means that the material of the molded body—the molding material—is in contact with the semiconductor chip. Particularly preferably, the molded body surrounds the semiconductor chip in a form-fit manner at least in places. The molded body consists of a material which is permeable for at least part of the electromagnetic radiation emitted by the optoelectronic semiconductor chip during operation of the semiconductor component or which is to be received by the latter. It is preferred that the molded body contains silicone or epoxy or consists of one of these two materials. Preferably, the optoelectronic semiconductor chip is molded or cast with the molding material of the molded body. That means that the molded body is preferably produced by means of a casting or pressing method. The molded body is a molding of the semiconductor chip and a housing of the semiconductor component at the same time.

According to at least one embodiment of the surface mountable semiconductor component, said semiconductor component comprises a mounting face, which is at least in places formed by a surface of the molded body. The mounting face of the semiconductor component relates to the surface of the semiconductor chip which faces a carrier—for example a circuit board—on which the surface mountable semiconductor component is mounted. The mounting face may be a supportive surface with which the semiconductor component rests on the carrier. To that end, the mounting face can be in mechanical contact with the carrier at least in places. Furthermore, it is possible that the mounting face is in contact with a connection material—for example a solder via which the surface mountable semiconductor component is in electrical contact. That means that the connection material covers parts of the mounting face and thus parts of the molded body.

As used herein, the fact that a layer or an element is arranged or applied “on” or “over” another layer or another element can mean that one layer or one element is in direct mechanical and/or electrical contact on the other layer or the other element. Furthermore, it may also mean that one layer or one element is indirectly arranged on or over the other layer or the other element. Further layers and/or elements may be arranged between one and the other layer.

According to at least one embodiment of the surface mountable semiconductor component, said surface mountable semiconductor component comprises a plurality of first contact elements and a plurality of second contact elements, wherein the plurality of first contact elements is electrically conductively connected to the first semiconductor layer and the plurality of second contact elements is electrically conductively connected to the second semiconductor layer and wherein the plurality of first and the plurality of second contact elements protrude through the molded body in the region of the mounting face. Preferably, the plurality of first contact elements is electrically conductively connected to the first semiconductor layer and the plurality of second contact elements is electrically conductively connected to the second semiconductor layer in a wireless manner, i.e., without using a bonding wire.

The contact elements of the surface mountable semiconductor component are provided to electrically contact the semiconductor component. Preferably, they are at least partially in the molded body. Preferably, the contact elements are externally accessible at the mounting face of the surface mountable semiconductor component. That means that the semiconductor component can be electrically contacted at the mounting face of the surface mountable semiconductor component. The contact elements may be arranged in the type of a matrix. For example, the first and/or second contact elements may each be arranged in one or in multiple rows. Preferably, either the first or the second contact elements are arranged exclusively in peripheral regions of the mounting face.

Due to the fact that not only one but a plurality of contact elements are provided for each polarity, it is advantageously achieved that a charge carrier injection into the semiconductor layers can be effected in multiple regions of the semiconductor components which are spaced apart from one another, which thereby achieves an increase in efficiency of the component. Moreover, the plurality of contact elements in the mounted state allows improved robustness to tensile, compressive and/or transversal stress. Finally, during the production process, part of the plurality of contact elements may form spacer elements between the semiconductor chip and an auxiliary carrier used in production, defining interspaces free of solid material, in which the molded body is formed in one of the following method steps. The plurality of contact elements achieves a good encapsulation of the semiconductor chip by means of the molded body in the region of the mounting face compared to a configuration that has only one contact element.

According to at least one embodiment, the semiconductor component further comprises side surfaces which have been produced by singulation and which bear singulation traces as a result. The side surfaces are the surfaces of the semiconductor component which surround the mounting face to the sides and which run in a direction transversely to the mounting face, for example.

The side walls are preferably produced by singulation. Thus, in particular, contour and shape of the side walls are not generated by a vesting or pressing process, but by means of a singulation process of the molded body. Singulation may be affected, for example, by sawing, cutting or producing a perforation and subsequent breaking. That means that a material removal preferably occurs during singulation of the individual semiconductor components. The side surface of the molded body and thus the side surfaces of the semiconductor component have then been produced by means of material removal. The side surfaces preferably bear traces of material removal.

Preferably, both the contact elements and part of the molded body is freely accessible at the mounting face of the surface mountable semiconductor component.

According to at least one embodiment of the optoelectronic semiconductor component, it is provided that the plurality of first contact elements and the plurality of second contact elements overlap with the semiconductor body in a plan view of the semiconductor component.

According to at least one embodiment of the optoelectronic semiconductor component, it is provided that the semiconductor chip comprises a carrier body with an electrically insulating design which is arranged on a side of the semiconductor body facing away from the mounting face. In particular, the semiconductor chip may comprise a carrier body made of sapphire and be arranged in a flip chip arrangement in the semiconductor component.

According to at least one embodiment of the optoelectronic semiconductor component, it is provided that the molded body is formed in sections to the semiconductor chip and the plurality of first and second contact elements. That means that the molded body preferably encloses the contact elements of the semiconductor component in a form-fit manner at least in places. The contact elements preferably each comprise one connection surface via which they can be electrically contacted from the outside of the semiconductor component. That means that the contact elements are not enclosed by the molded body at least on the connection surface. It is preferred for the molded body to enclose the semiconductor chip from all sides.

According to at least one embodiment of the optoelectronic semiconductor component, it is provided that each of the contact elements comprises a connection base and a cap element which protrudes vertically from the mounting face. For example, each of the cap elements protrudes vertically from the mounting face by at least 30 μm, preferably by at least 50 μm. As an alternative or in addition, each of the cap elements may vertically protrude from the mounting face by no more than 500 μm, preferably by 200 μm at the most.

This particularly means that each of the cap elements may vertically protrude from the molded body by at least 30 μm, preferably by at least 50 μm. As an alternative or in addition, each of the cap elements may vertically protrude from the molded body by no more than 500 μm, preferably by 200 μm at the most.

As used herein, the term “vertical direction” relates to a direction perpendicular to a main extension plane of the semiconductor body and/or to the mounting face. As used herein, the term “lateral direction” relates to a direction parallel to a main extension plane of the semiconductor body and/or to the mounting face. The phrase “plan view of the component” relates to a view along a vertical direction and thus corresponds to a projection along a vertical direction.

The connection base may consist of copper and have a cylindrical design. The cap element may consist of copper or tin and may be designed as a solder bump, for example. In one embodiment, the connection bases act as spacer elements between the semiconductor chip and an auxiliary carrier during the production process. In one embodiment, the cap element will be formed but not before first forming the molded body. The cap element preferably has a hemispherical design.

The cap elements, which protrude from the mounting face, can be designed as a ball grid array. These may advantageously act as spacer elements between the mounting face and a carrier (for example a circuit board), on which the surface mountable semiconductor component is mounted, resulting in interspaces which can advantageously be filled by a reflecting intermediate layer. As a result, it is not required to provide a mirror layer in the semiconductor layer, which reflects light emitted by the semiconductor body in the direction away from the mounting face, which leads to cost savings.

Furthermore, solder bumps may effect a self-centering when being mounted on a carrier, facilitating a precise mounting process. Furthermore, the grid array of solder bumps in the mounted state allows increased robustness of the component to tensile, compressive and/or transversal stress.

According to at least one embodiment of the optoelectronic semiconductor component, it is provided that the molded body in the region of the mounting face has a height of more than 10 μm, preferably more than 30 μm, in particular more than 50 μm, in order to ensure sufficient mechanical stability of the component. At this height, a production of the molded body using the spacer elements is enabled, while the interspaces between the semiconductor chip and auxiliary carrier can only insufficiently by filled with molding material in case of smaller values.

As an alternative or in addition, it is provided that the molded body has a height of less than 200 μm, preferably less than 150 μm, in particular less than 100 μm in the region of the mounting face. This achieves sufficient heat dissipation of the component.

According to at least one embodiment of the optoelectronic semiconductor component, it is provided that the molded body is designed in one piece, in particular in one single method step. Compared over components known from the prior art, where there is a risk of separation of silicone elements cured in succession, the mechanical adhesion of the molded body to the semiconductor chip is increased. This is rather due to a form-fit between the two elements than to the adhesion between the semiconductor chip and the molded body, which form-fit is produced in that the molding material cools during production of the components and shrinks as a result.

For example, a molding material containing silicone is used, which is cured at a temperature of more than 100° C. Due to its very large thermal expansion coefficient of typically more than 200 ppm/K, the molding material of silicone shrinks more than the semiconductor chip, resulting in a pressing from all sides.

According to at least one embodiment of the optoelectronic semiconductor component, it is provided that a varistor paste is applied between the plurality of first contact elements and the plurality of second contact elements, which is designed to protect the optoelectronic semiconductor chip from an electrostatic discharge.

According to at least one embodiment of the optoelectronic semiconductor component, a simple flip chip arrangement is selected, in which there is no need for a complex wiring in view of the contacting of the semiconductor layers. For example, in a plan view of the component, the first or the second contact elements may be connected to the first or second semiconductor layer in the same regions that they are accessible in the region of the mounting face. This corresponds to an embodiment that can be achieved in a simple and thus cost-efficient manner. However, on a carrier (for example a circuit board) where the surface mountable semiconductor component is mounted, a relatively complex contacting geometry is to be selected usually.

According to at least one embodiment of the optoelectronic semiconductor component, it is provided that the plurality of first contact elements is electrically conductively connected to the first semiconductor layer via a first connection layer and that the plurality of second contact elements is electrically conductively connected to the second semiconductor layer via a second connection layer and the first connection layer and the second connection layer overlap with each other in a plan view of the semiconductor component. This corresponds to a (more complex) wiring in the interior of the semiconductor chip. To that end, a more simple contacting geometry can be selected on the level of the carrier.

According to at least one embodiment, the molded body contains a luminescence conversion material. The luminescence conversion material is preferably suitable to absorb at least part of the electromagnetic radiation of a first wavelength range emitted in operation of the optoelectronic semiconductor chip and/or to be received by the semiconductor chip and to emit electromagnetic radiation of a second wavelength range, which is different from the first wavelength range. For example, the semiconductor component may be designed to produce white mixed light.

According to at least one embodiment of the optoelectronic semiconductor component, it is provided that a luminescence conversion layer is at least sectionally arranged between the molded body and the semiconductor chip.

A method for producing a plurality of surface mountable semiconductor components is provided. The method comprises the following steps:
a) Providing an auxiliary carrier;
b) Providing a plurality of optoelectronic semiconductor chips, wherein each of the semiconductor chips comprises a semiconductor body which includes a semiconductor layer sequence with an active region provided for producing and/or receiving electromagnetic radiation, which active region is arranged between the first semiconductor layer and a second semiconductor layer,
c) Fastening the multitude of semiconductor chips on the auxiliary carrier, wherein the semiconductor chips are spaced from one another in a lateral direction and interspaces free of solid material are provided between each of the semiconductor chips and the auxiliary carrier;
d) Forming a molded body compound enclosing the semiconductor chips,
f) Removing the auxiliary carrier; and
g) Singulating the solid body compounds into a multitude of optoelectronic semiconductor components, wherein each semiconductor comprises at least one semiconductor chip, a plurality of first contact elements, a plurality of second contact elements, and part of the solid body compound as a molded body.

In particular, the molded body compound can be produced by means of a casting method. All production methods in which a molding material is introduced in a predetermined mold and in particular subsequently cured count among casting methods. In particular, the term casting methods includes casting, injection molding, transfer molding, and compression molding. Preferably, the molded body compound is formed by compression molding or by a film assisted transfer molding method. In the illustrated method step, the semiconductor chip connects to the molding material used for forming the solid body compound preferably in a form-fit manner.

According to at least one embodiment of the method, it is provided that each of the semiconductor chips comprises a plurality of spacer elements, by which the interspaces are formed which form at least parts of the first and second contact elements of the finished components.

According to at least one embodiment of the method, it is provided that a structured auxiliary carrier is provided with a non-even surface and that the interspaces free of solid material emerge at least indirectly by fastening the semiconductor chips on the non-even surface of the auxiliary carrier.

By the use a structured auxiliary carrier, designing spacer elements for example in the form of connection bases, which are typically designed by a galvanic process, may be omitted, reducing the production costs. In a later method step, the contact elements, e.g., in the form of solder bumps, are placed in the regions where the structured carrier contacts the semiconductor chips.

The above described method for producing surface mountable semiconductor components is particularly suitable for the production of the surface mountable semiconductor component. Features indicated in connection with the method can thus be considered for the semiconductor component or vice versa.

### BRIEF DESCRIPTION OF THE DRAWINGS

Further features, configurations and developments result from the following description of the exemplary embodiment in conjunction with the figures.

Like, similar or equivalent elements are provided with the same reference numerals throughout the drawings.

The figures and the size ratios of the elements indicated in the Figures are not necessarily to scale. Individual elements and in particular layer thicknesses may rather be illustrated in an exaggerated size for a better understanding and/or for the sakes of clarity.

The Figures show in:

FIGS. 1 to 3 a first exemplary embodiment for a surface mountable semiconductor component,

FIGS. 4 and 5 another exemplary embodiment for a surface mountable semiconductor component,

FIGS. 6 and 7 another exemplary embodiment for an optoelectronic semiconductor component,

FIG. 8 an arrangement of a surface mountable semiconductor component according to the invention on a circuit board,

FIGS. 9 to 13 an exemplary embodiment for a method for producing surface mountable semiconductor components based upon intermediate steps illustrated in a schematic sectional view, and

FIG. 14 another exemplary embodiment for a surface mountable semiconductor component.

### DETAILED DESCRIPTION OF ILLUSTRATIVE EMBODIMENTS

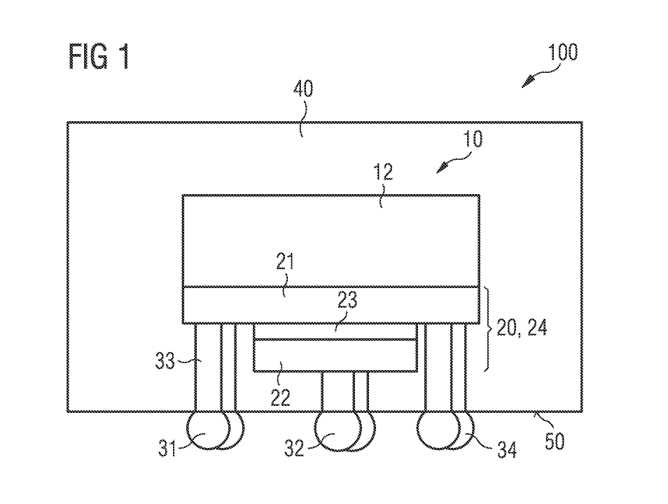

FIGS. 1 to 3 show an exemplary embodiment for a surface mountable semiconductor component. The semiconductor component, generally indicated with 100, comprises an optoelectronic semiconductor chip 10 which is enclosed by a molded body 40 of silicone. The optoelectronic semiconductor chip 10 comprises a semiconductor body 20 which is arranged on a carrier body 12 of sapphire and comprises a semiconductor layer sequence 24, in which an active region 23 is designed between a first semiconductor layer 21 and a second semiconductor layer 22. A mounting face 50 is designed on an underside of the component 100, which is at least in places formed by a surface of the molded body 40. Furthermore, the semiconductor component 100 comprises a plurality of first contact elements 31 and a plurality of second contact elements 32, which protrude through the molded body in the region of the mounting face 50. The first contact elements are electrically conductively connected to the first semiconductor layer and the second contact elements 32 are electrically conductively connected to the second semiconductor layer 22. In the present exemplary embodiment, the second semiconductor layer 22 is removed in the peripheral regions of the semiconductor chip and is directly contacted there by the first contact elements 31. Both the first semiconductor layer 21 and the second semiconductor layer 22 are each connected to the contact elements 31, 32 in regions where the component is contacted from the outside in a plan view. Optionally, a mirror layer, for example made of silver, may be designed between the second semiconductor layer 22 and the contact elements 32 (which is not shown).

Each of the contact elements 31, 32 comprises a connection base 33, which penetrates through the molded body 40 and terminates flush with the mounting surface 50, as well as a cap element 34, which vertically protrudes from the mounting face. The connection bases 33 may have the shape of cylinders and may consist of copper, for example. The cap elements 34 are designed as solder bumps, for example. The connection bases 33 have a height (dimension in the vertical direction) between 10 μm and 150 μm. At the same time, this is the height of the molded body 40 in the region of the mounting face 50 (indicated with reference numeral 41).

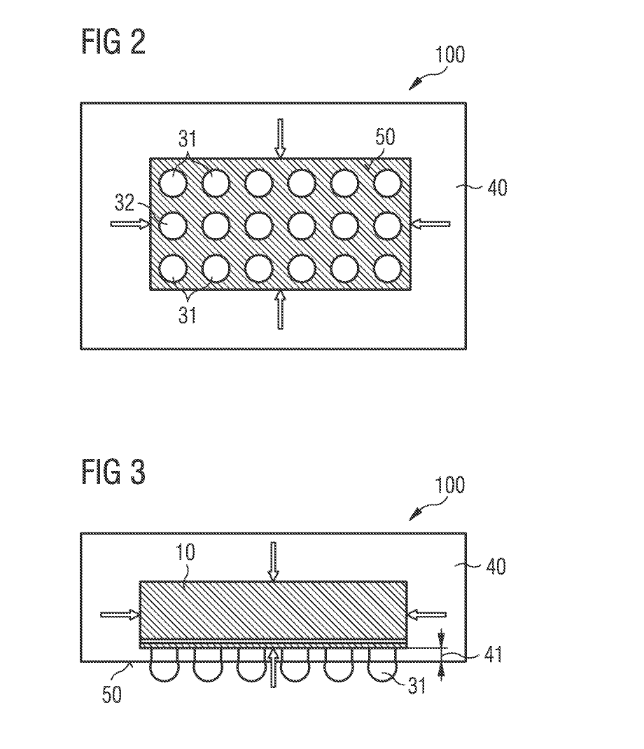

In the exemplary embodiment illustrated in FIGS. 1 to 3, the semiconductor chip is a sapphire chip in a flip chip arrangement and is surrounded by a molded body with a thickness of 150 μm except for the region of the mounting face 50 (underside of the component). The arrows illustrated in FIGS. 2 and 3 indicate the pressure of the molded body 40 to the semiconductor chip 10, which ensures a good mechanical stability between both elements. For example, the connection bases 33 may be generated galvanically during production of the semiconductor chip 10, while the cap elements 34 are formed but not before first forming the molded body 40.

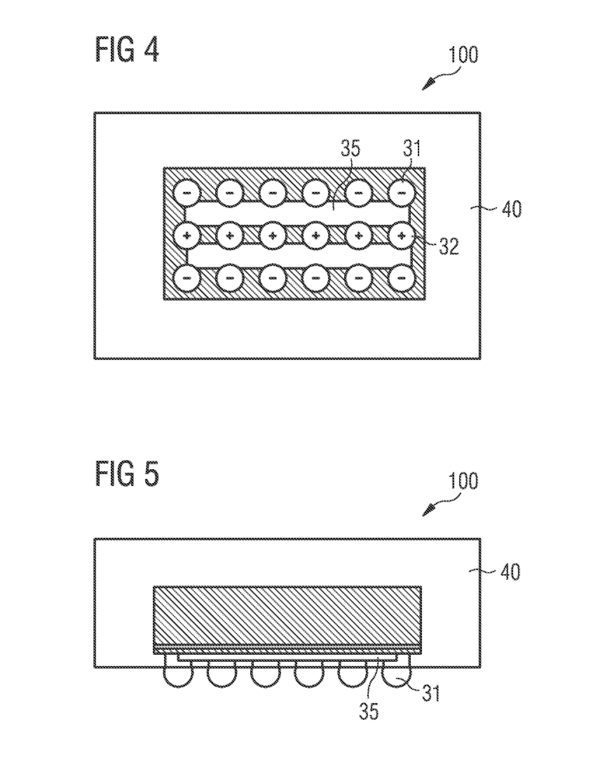

In contrast to the exemplary embodiment shown in FIGS. 1 to 3, a varistor paste 35 is applied between the plurality of first contact elements 31 and the plurality of second contact elements 32 in the exemplary embodiment illustrated in FIGS. 4 and 5, which paste is designed for protection of the optoelectronic semiconductor chip 10 from an electrostatic discharge. The use of a varistor paste, which may contain a polymer with semiconductor particles such as particles made of silicon carbide, comes with the advantage that additional efforts are not required due to the installation of an additional switch in the type of a protective diode. Varistor pastes provide forward voltages in the range between 500 and 1000 V.

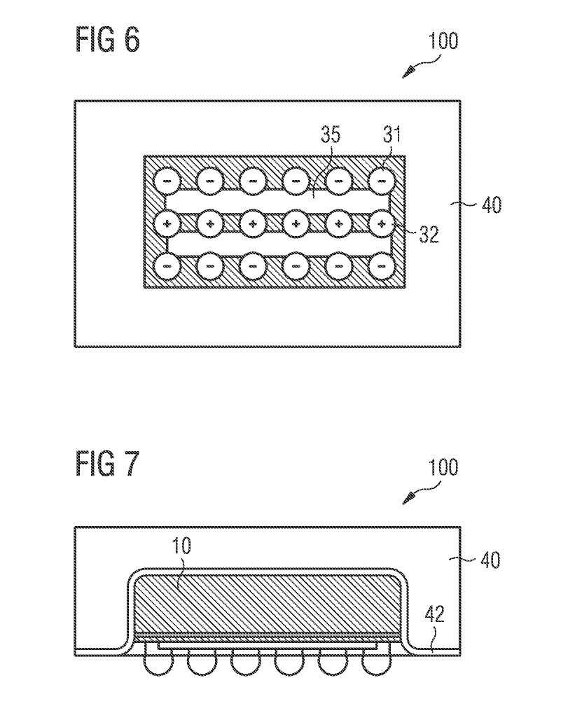

In the exemplary embodiment illustrated in FIGS. 1 to 5, the molded body 40 may contain a luminescence conversion material. In contrast, FIGS. 6 and 7 show an exemplary embodiment in which the molded body 40 is free of a luminescence conversion material and a luminescence conversion layer 42 is at least sectionally arranged between the molded body 40 and the semiconductor chip 10. Said luminescence conversion layer 42 may be formed by sedimentation, spray coating or electrophoretic deposition, for example. In the illustrated exemplary embodiment, said layer is a sprayed luminescence conversion layer which is surrounded by a molded body 40 consisting of transparent silicone for fixing and mechanical stabilization here. In addition, the molded body 40 may contain fused silica which increase the mechanic stability and strength of the component.

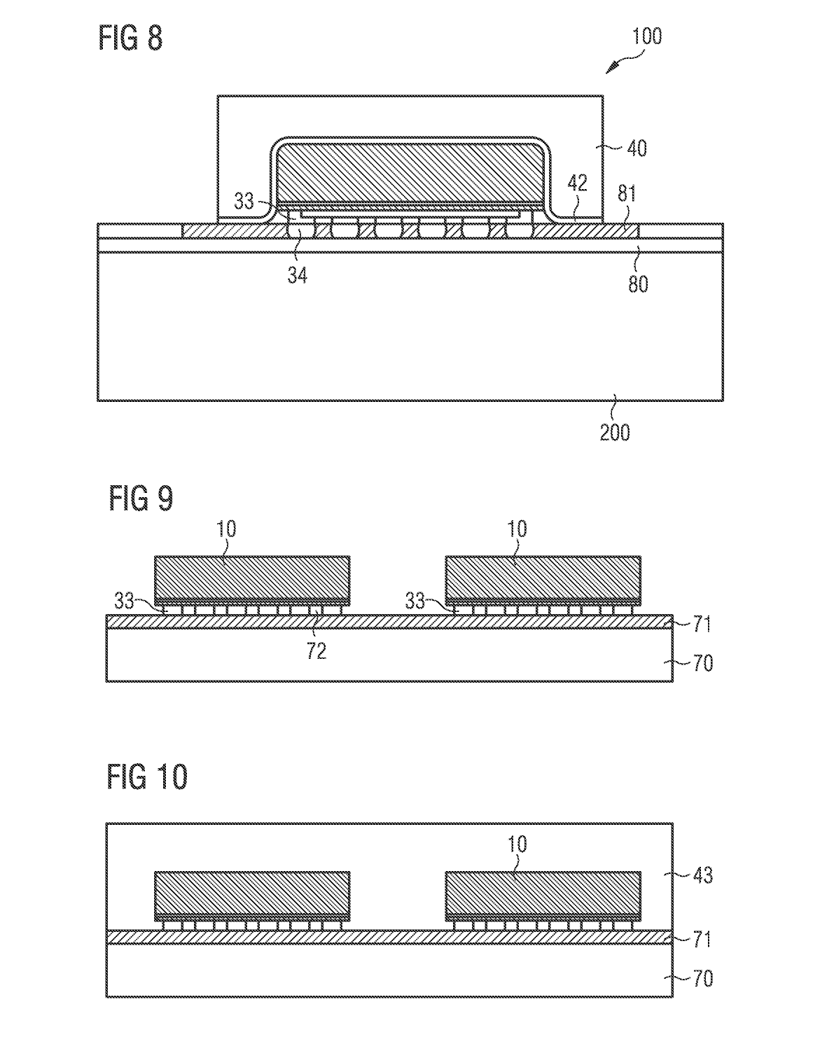

FIG. 8 shows the semiconductor component illustrated in FIGS. 6 and 7 in a mounted state. The component 100 is soldered to conductor tracks 80 of a circuit board 200 by the solder bumps thereof. The latter are acting as spacer elements between the mounting face 50 of the component 100 and the surface of the circuit board 200. An intermediate layer 81 may be formed in the resulting interspaces, which acts as a reflector. This achieves that forming a reflecting layer inside the semiconductor chip 10 is no longer required. While the surface of the circuit board 200 is usually not reflecting, since it consists of epoxy and copper, the intermediate layer 81 with the reflecting design advantageously achieves a deflection of light away from the circuit board 200.

FIGS. 9 to 13 illustrate an exemplary embodiment for a method for producing a multitude of surface mountable semiconductor components. In the method step illustrated in FIG. 9, a plurality of singulized semiconductor chips 10, the semiconductor layers of which are electrically conductively connected to a plurality of connection sockets 33 made of copper, are fastened to an auxiliary carrier 70 by means of an adhesive layer 71. Here, the semiconductor chips 10 are arranged on the auxiliary carrier 71 in such a way that the semiconductor bodies face the auxiliary carrier 71 viewed from the carrier bodies of the semiconductor chips 10. The semiconductor chips 10 are arranged in a grid array and spaced from one another in a lateral direction, i.e., in a direction parallel to the main extension plane of the auxiliary carrier 71.

The adhesive layer 71 can be a double-sided adhesive film or consist of silicone which additionally acts as an anti-stick layer. Interspaces 72 free of solid material are formed between each of the semiconductor chips 10 and the auxiliary carrier 70, which spaces develop in the regions between the connection bases 33. If a thin silicone layer (with a thickness of between 10 and 20 μm, for example) is used, the intermediate spaces 72 can readily be filled with molding material in a subsequent method step. However, using the film as an adhesive layer comes with the disadvantage that it is easily flexible and thus leads to the development of interspaces 72 of reduced size.

In the subsequent method step shown in FIG. 10, a molded body compound 43 is produced by means of compression molding, said body surrounding the semiconductor chips 10 from all sides and in particular closing the intermediate spaces 72 between the connection bases 33 of semiconductor chips 10. Silicones, acrylates and epoxies are used as molding material. As an alternative, the molded body compound can be formed by an injection molding process, wherein the use of blue-stable or UV stable thermoplastics, polycyclohexylenedimethylene terephthalate (PCT), is advantageous. The use of thermosetting polymers, such as silicone, is possible as well. The molding material can be filled with fillers that contain silicon oxide, boron nitride, aluminum oxide, aluminum nitride or phosphors, for example.

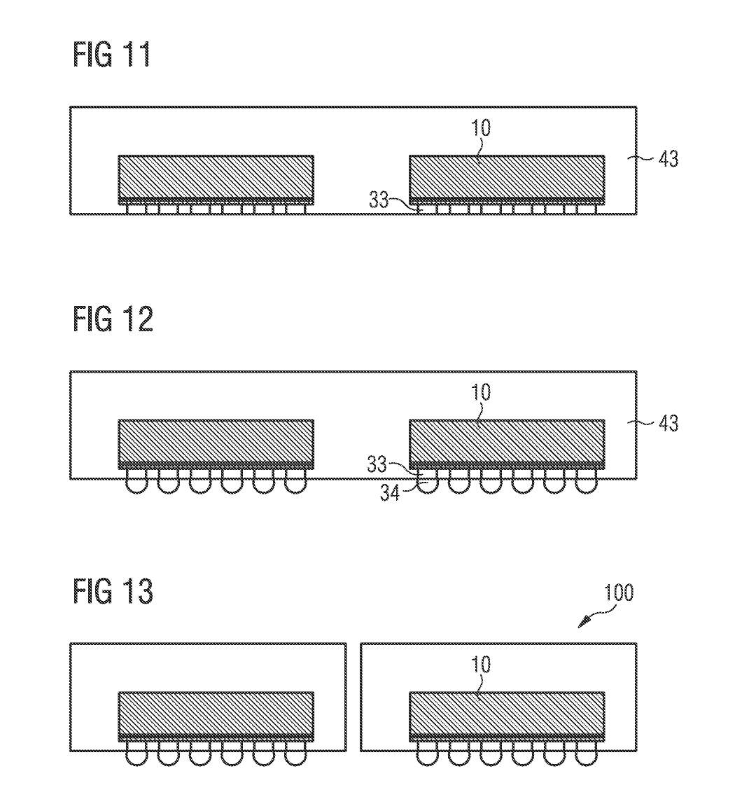

In the method step illustrated in FIG. 11, the auxiliary carrier 70 is removed by delamination. This may be effected by heating the adhesive layer and/or dissolving the adhesive layer 71 by chemical processes and/or by using a mechanical force.

In the method step illustrated in FIG. 12, cap elements 34 in the form of solder bumps 34 are formed on the connection bases 33. The solder bumps 34 are re-melted in a thermal process. Advantageously, a flux agent is used to bond the solder bumps and to improve the re-melting behavior. The solder can be applied galvanically.

For singulation into semiconductor components 100 (see FIG. 13), the molded body compound 43 is separated along singulation lines. This can be effected mechanically, e.g., by means of sawing, cutting or punching, chemically, e.g., by means of etching, and/or by means of coherent radiation, e.g., by laser ablation.

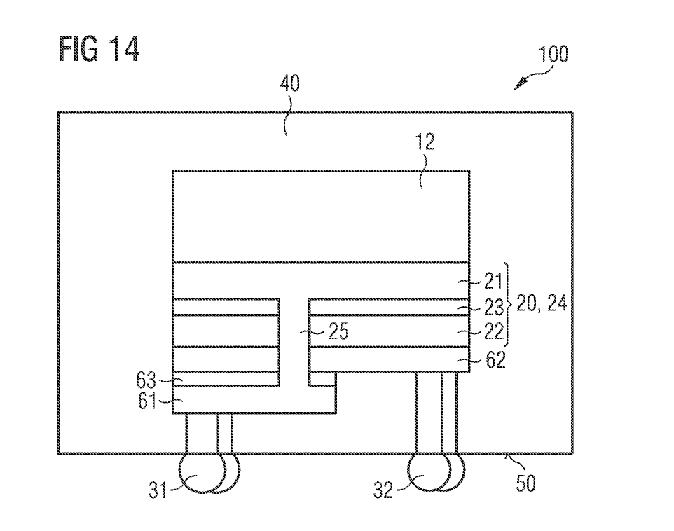

FIG. 14 shows another exemplary embodiment of an optoelectronic surface-mountable semiconductor component in which compared to the exemplary embodiments described in the foregoing a more complex wiring inside the semiconductor chip 10 is provided, thereby allowing the selecting of a more simple contacting geometry on the level of the carrier on which the surface-mountable semiconductor component is to be mounted later.

The plurality of first contact elements 31 is electrically connected to the first semiconductor layer 21 via a first connection layer 61. The plurality of second contact elements 32 is electrically conductively connected to the second semiconductor layer 22 via a second connection layer 62. An insulation layer 63 is arranged between the first connection layer 61 and the second connection layer 62. A cut-out 25 is provided in the semiconductor layer sequence 24, which extends through the insulation layer 63, the second connection layer 62, the second semiconductor layer 22 and the active region 23 into the first semiconductor layer 21 and which is at least partially filled with electrically conductive material. The application of an electric voltage between the first contact elements 31 and the second contact elements 32 allows charge carriers to be injected into the active region 23 from opposite directions and recombine there whilst emitting radiation.

In a plan view of the semiconductor component, the first connection layer 61 and the second connection layer 62 overlap each other. The geometry described makes it possible to contact the semiconductor layers in regions which are different from the regions in which the semiconductor component is contacted externally, viewed in a plan view of the semiconductor component. The second connection layer 62 may be designed as a mirror layer, e.g., of silver.

The invention is not limited by the description in conjunction with the exemplary embodiments. The invention rather comprises any new feature as well as any combination of features, in particular including any combination of features in the patent claims, even if said feature or said combination per se is not explicitly indicated in the patent claims or exemplary embodiments.

1-15. (canceled)

16. A surface-mountable semiconductor component comprising:
an optoelectronic semiconductor chip;
a plurality of first contact elements;
a plurality of second contact elements; and
a molded body,
wherein the optoelectronic semiconductor chip comprises a semiconductor body comprising a semiconductor layer sequence with an active region provided for producing and/or receiving electromagnetic radiation and arranged between a first semiconductor layer and a second semiconductor layer,
wherein the plurality of first contact elements is electrically conductively connected to the first semiconductor layer and the plurality of second contact elements is electrically conductively connected to the second semiconductor layer,
wherein the molded body at least partially encloses the optoelectronic semiconductor chip,
wherein the semiconductor component comprises a mounting face formed by a surface of the molded body at least in places, and
wherein the plurality of first and the plurality of second contact elements protrude through the molded body in a region of the mounting face.

17. The semiconductor component according to claim 16, wherein the plurality of first contact elements and the plurality of second contact elements overlap with the semiconductor body in a plan view on the semiconductor component.

18. The semiconductor component according to claim 16, wherein the optoelectronic semiconductor chip comprises a carrier body with an electrically insulating design arranged on a side of the semiconductor body facing away from the mounting face.

19. The semiconductor component according to claim 16, wherein the molded body is formed at least in sections to the optoelectronic semiconductor chip and to the plurality of first and second contact elements.

20. The semiconductor component according to claim 16, wherein the molded body encloses the optoelectronic semiconductor chip from all sides.

21. The semiconductor component according to claim 16, wherein each contact element comprises a connection base and a cap element protruding vertically from the mounting face.

22. The semiconductor component according to claim 16, wherein the molded body contains silicone or epoxy.

23. The semiconductor component according to claim 16, wherein the molded body has a height of between 10 μm and 150 μm in the region of the mounting face.

24. The semiconductor component according to claim 16, wherein the molded body is one piece.

25. The semiconductor component according to claim 16, wherein a varistor paste is applied between the plurality of first contact elements and the plurality of second contact elements, the paste configured to protect the optoelectronic semiconductor chip from an electrostatic discharge.

26. The semiconductor component according to claim 16, wherein the plurality of first contact elements is electrically conductively connected to the first semiconductor layer via a first connection layer and the plurality of second contact elements is electrically conductively connected to the second semiconductor layer via a second connection layer and the first connection layer and the second connection layer overlap in a plan view of the semiconductor component.

27. The semiconductor component according to claim 16, wherein the molded body contains a luminescence conversion material.

28. The semiconductor component according to claim 16, wherein a luminescence conversion material layer is arranged at least in sections between the molded body and the optoelectronic semiconductor chip.

29. A method for producing a plurality of surface-mountable optoelectronic semiconductor components, the method comprising:
providing an auxiliary carrier;
providing a multitude of optoelectronic semiconductor chips, wherein each of the semiconductor chips comprises a semiconductor body comprising an active region provided for producing and/or generating electromagnetic radiation and arranged between a first semiconductor layer and a second semiconductor layer,
fastening the multitude of semiconductor chips on the auxiliary carrier, wherein the semiconductor chips are spaced from one another in a lateral direction and interspaces free of a solid material are provided between each of the semiconductor chips and the auxiliary carrier;
forming a molded body compound enclosing the semiconductor chips;
removing the auxiliary carrier; and
singulating the molded body compound into the plurality of optoelectronic semiconductor components, wherein each semiconductor component comprises at least a semiconductor chip, a plurality of first contact elements, a plurality of second contact elements and part of the molded body compound as a molded body.

30. The method according to claim 29, wherein each of the semiconductor chips comprises a plurality of spacer elements by means of which the interspaces are formed and which form at least parts of the first and second contact elements of the finished components.

31. A surface-mountable semiconductor component comprising:
an optoelectronic semiconductor chip;
a plurality of first contact elements;
a plurality of second contact elements; and
a molded body,
wherein the optoelectronic semiconductor chip comprises a semiconductor body comprising a semiconductor layer sequence with an active region provided for producing and/or receiving electromagnetic radiation and arranged between a first semiconductor layer and a second semiconductor layer,
wherein the plurality of first contact elements is electrically conductively connected to the first semiconductor layer and the plurality of second contact elements is electrically conductively connected to the second semiconductor layer,
wherein the molded body at least partially encloses the optoelectronic semiconductor chip,
wherein the semiconductor component comprises a mounting face formed by a surface of the molded body at least in places,
wherein the plurality of first and the plurality of second contact elements protrude through the molded body in a region of the mounting face, and
wherein each contact element comprises a connection base and a cap element which protrudes vertically from the mounting face.

32. The semiconductor component according to claim 31, wherein a varistor paste is located between the plurality of first contact elements and the plurality of second contact elements, the paste configured to protect the optoelectronic semiconductor chip from an electrostatic discharge.

33. A surface-mountable semiconductor component comprising:
an optoelectronic semiconductor chip;
a plurality of first contact elements;
a plurality of second contact elements; and
a molded body,
wherein the optoelectronic semiconductor chip comprises a semiconductor body comprising a semiconductor layer sequence with an active region provided for producing and/or receiving electromagnetic radiation and arranged between a first semiconductor layer and a second semiconductor layer,
wherein the plurality of first contact elements is electrically conductively connected to the first semiconductor layer and the plurality of second contact elements is electrically conductively connected to the second semiconductor layer,
wherein the molded body at least partially encloses the optoelectronic semiconductor chip,
wherein the semiconductor component comprises a mounting face formed by a surface of the molded body at least in places,
wherein the plurality of first and the plurality of second contact elements protrude through the molded body in a region of the mounting face, and
wherein a varistor paste is located between the plurality of first contact elements and the plurality of second contact elements, the paste configured to protect the optoelectronic semiconductor chip from an electrostatic discharge.
